(19) United States
(12) Patent Application Publication
(10) Pub. No.: US 2011/0147060 A1
(43) Pub. Date: Jun. 23, 2011

(54) DIELECTRIC FILM, DIELECTRIC ELEMENT, AND PROCESS FOR PRODUCING THE DIELECTRIC ELEMENT

(76) Inventors: Minoru Osada, Ibaraki (JP); Takayoshi Sasaki, Ibaraki (JP)

(21) Appl. No.: 12/993,952

(22) PCT Filed: May 25, 2009
(86) PCT No.: PCT/JP2009/059550

§ 371 Date: Feb. 7, 2011

(30) Foreign Application Priority Data
May 23, 2008 (JP) 2008-135379

(51) Int. Cl. H05K 1/00; B32B 5/00; B32B 37/00; B05D 1/18; B05D 1/20; C04B 35/462

(52) U.S. Cl. 174/258; 428/220; 156/60; 427/472; 216/94; 156/281; 216/95; 501/134

(57) ABSTRACT

A monolayer or a multilayer of niobic acid nanosheets is attached to form a dielectric film, and other electrode is arranged on the surface of the dielectric film to construct a dielectric element, and the dielectric element thus provided realizes both high permittivity and good insulating properties even in a nano-region. Also provided is a method of producing the element at low temperatures with no influence of substrate interface deterioration and composition deviation thereof. The method entirely solves the problems of substrate interface deterioration and the accompanying composition deviation and electric incompatibility, and solves the intrinsic problem of “size effect” that the film thickness reduction to a nano-level lowers the specific permittivity and increases the leak current, and the method takes advantage of the peculiar properties and good ability of texture and structure regulation that the niobic acid nanosheet has.

### TECHNICAL FIELD

The present invention relates to a dielectric film and to a dielectric element and a process for producing it capable of simultaneously realizing high permittivity and good insulating properties and favorable for application to broad field of electronic materials, such as DRAM memory for personal computers, multilayer capacitor for mobile telephones, gate insulator for transistors and others.

### BACKGROUND ART

Of dielectric elements, those having a high permittivity are utilized in all electronic instruments such as computers, mobile telephones and others, and act in the core of electronic instruments, for example, in the memory, the transistor gate insulating film or the like thereof. The current remarkable development of electronic instruments such as personal computers, mobile telephones and others is supported by the advanced functions of dielectric elements. Heretofore, the development of dielectric elements and the advanced functions thereof have been realized by the technology of microstructuring and high-integration (top-down technology) based on the forefront of film formation technology and semiconductor fabrication technology. For example, in DRAM and transistor, the thickness of the dielectric thin film is being reduced year by year, as aiming at capacity increase; and a nanometer-order thin film structure has already been used everywhere in the devices.

Of many dielectric materials, titanium oxides that include TiO₆ octahedrons such as (Ba,Sr)TiO₃, rutile-type TiO₂ or the like have excellent dielectric properties (specific permittivity, at least 100); and from the beginning of 1990's, application studies of the oxides to electronic devices such as memory cells, transistors and others have been made. However, these oxide materials have some problems in that they may cause substrate interface deterioration and also composition deviation and electric incompatibility with it, owing to thermal annealing in the process of producing them, and the problems are bottlenecks in advancing the functions of those dielectric elements. In addition, many of these materials have an intrinsic problem in that, when their film is thinned to a nano-level, aiming at capacity increase, then their specific permittivity lowers, thereby causing the “size effect” of increasing leak current. Accordingly, the technology of realizing microstructured, high-density and high-integration devices by the use of existing dielectric materials faces imminent physical and economical limitations; and for brake-through to realization of next-generation devices, it is now desired to create a dielectric element having high permittivity and good insulating properties even in a nano-region, and to develop a method for producing the element of the type at low temperatures with no influence of substrate interface deterioration and composition deviation thereon.

### DISCLOSURE OF THE INVENTION

### Problems that the Invention is to Solve

Under the background as above, an object of the invention is to provide a novel technical means that solves the existing problems, realizes both high permittivity and good insulating properties even in a nano-region, and enables element production at low temperatures with no influence of substrate interface deterioration and composition deviation thereon.

### Means for Solving the Problems

The present inventors have assiduously studied for the purpose of solving the above-mentioned problems and, as a result, have found that a niobic acid nanosheet including NbO₆ octahedrons inside the crystal can be a high-permittivity dielectric nanomaterial capable of functioning even though having a nona-level thickness, and that, when a dielectric element is produced through self-organization reaction at room temperature using the nanomaterial as backbone blocks, then the problem with thermal annealing in existing semiconductor production processes can be solved; and on the basis of these findings, the inventors have completed the present invention.

Specifically, the invention is characterized by the following:

The invention 1 is a dielectric film of a monolayer or a laminate of a nanosheet composed of niobic acid octahedral blocks.

The invention 2 is the dielectric film of the invention 1, wherein the niobic acid nanosheet is represented by any of compositional formulae TiNbO_{5-d}, Ti₂NbO_{7-d}, Ti₅NbO_{14-d}, Nb₃O_{8-d}, Nb₆O_{17-d}, TiNb_{1-y}Ta_{y}O_{5-d}, Ti₂Nb_{1-y}Ta_{y}O_{7-d}, Ti₅Nb_{1-y}Ta_{y}O_{4-d}, (N_{1-y}Ta_{y})₃O_{8-d}, (Nb_{1-y}Ta_{y})₆O_{17-d}, Ti_{1-z}Nb_{z}O₅, Ti_{2-z}Nb_{z}O₇, Ti_{5-z}Nb_{z}O₁₄ (0<y≦1; −0.5≦z≦0.5 (excluding z=0); d (oxygen defect)=0 to 2).

The invention 3 is the dielectric film of the invention 1 or 2, wherein the nanosheet has a sheet-like form having a thickness of at most 5 nm (corresponding to a few atoms) and a lateral size of from 100 nm to 100 μm.

The invention 4 is the dielectric film of any of the inventions 1 to 3, wherein the nanosheet is obtained by cleaving any of the phyllo-structured niobium oxides or their hydrates represented by the following compositional formulae.

The invention 5 is a dielectric element comprising electrodes arranged on and below a dielectric film, wherein the dielectric film is the dielectric film of any of the inventions 1 to 4.

The invention 6 is the dielectric element of the invention 5, wherein the thickness of the dielectric film is at most 20 nm and the specific permittivity thereof is at least 50.

The invention 7 is a method for producing a dielectric element of any of the invention 5 or 6, which comprises attaching a monolayer or a multilayer of the niobic acid nanosheets of any of the inventions 1 to 4 to at least one electrode substrate to constitute the dielectric element, thereby forming a dielectric film, and arranging other electrode on the surface of the dielectric film.

The invention 8 is the method for producing a dielectric element of the invention 7, wherein an electrode substrate having adsorbed a cationic organic polymer on its surface is dipped in a colloid solution where the niobium acid nanosheets are suspended, and the niobic acid nanosheets are thereby adsorbed by the polymer through electrostatic interaction.

The invention 9 is the method for producing a dielectric element of the invention 8, wherein the dielectric film is, after formed, irradiated with UV rays to thereby remove the organic polymer from the substrate surface.

The invention 10 is the method for producing a dielectric element of the invention 7, wherein a monolayer film is formed in which niobic acid nanosheets are bonded in parallel to each other according to a Langmuir-Blodgett process, and the monolayer film is attached to the electrode substrate.

The invention 11 is the method for producing a dielectric element of the invention 7, 8 or 11, wherein ultrasonic waves are given to the niobic acid nanosheets being attached to the substrate to thereby remove the overlapped part of the nanosheets.

The invention 12 is the method for producing a dielectric element of any of the inventions 7 to 11, wherein the step of attaching the niobic acid nanosheets to the electrode substrate is repeated to form a multilayered dielectric film of the niobic acid nanosheets.

### ADVANTAGE OF THE INVENTION

The invention 1 has made it possible to utilize peculiar properties and good ability of texture and structure regulation that the niobic acid nanosheet has, and has realized both high permittivity and good insulating properties even in a nano-region.

The invention 2 has further enabled artificial reconstruction of the niobic acid nanosheet that includes NbO₆ octahedrons of high-function dielectric blocks, and has therefore made it possible to produce and plan the thin film having more excellent dielectric properties than existing titanium oxide dielectric substances.

Further, the invention 3 uses the niobic acid nanosheet, and has therefore enabled artificial regulation of the thickness thereof and artificial reconstruction of the niobic acid nanosheet suitable to the type of usage thereof, and accordingly, it has enabled production and planning of the thin film having excellent dielectric properties.

The invention 4 has made it possible to extract and artificially reconstruct, as a nanosheet of a simple substance thereof, the phyllo-structured niobium oxide that includes NbO₆ octahedrons known as a high-functional dielectric material, as the basic blocks therein, and therefore has made it possible to produce and plan the thin film having more excellent dielectric properties than existing titanium oxide dielectric substances.

According to the invention 5, further, there is provided the dielectric element favorable for application to a broad field of electronic materials such as memories, capacitors, gate insulators for transistors and others.

According to the invention 6, both thickness reduction and capacity level elevation have been attained simultaneously that have heretofore been difficult at all in existing dielectric elements.

According to the invention 7, further, even the poorly self-sustaining niobic acid nanosheet can be held by an electrode substrate and can be handled with ease, and the production of the dielectric element of the invention 5 or 6 is thereby secured.

Further, the invention 8 has enabled the inexpensive room-temperature solution process where an electrode substrate coated with a cationic organic polymer on its surface is used, and therefore has made it possible to provide the high-performance dielectric element with evading the problems of substrate interface deterioration and composition deviation in existing element production processes. In addition, this has realized the inexpensive, low environmental-load process not requiring a large-scale vacuum apparatus and an expensive film formation apparatus that are the mainstream of existing dielectric film processes.

Further, the invention 9 has made is possible to produce the inorganic dielectric element from which an organic material such as a polymer or the like has been removed, entirely in the room-temperature process, and has therefore provided the high-performance dielectric element, entirely solving the problems of substrate interface deterioration and composition deviation associated with the heat treatment step of existing production processes.

According to a Langmuir-Blodgett process, the invention 10 has made it possible to produce the high-quality dielectric film in which a niobic acid nanosheet is attached densely to the surface of a substrate with no gap therebetween, not using an organic polymer such as a cationic organic polymer, and therefore, has made it possible to produce the high-performance dielectric element in which the defects to cause circuit current leakage are removed or reduced, directly according to the inexpensive room-temperature solution process.

Further, the invention 11 has made it possible to produce the high-quality dielectric film in which a niobic acid nanosheet is attached densely to the surface of a substrate with no gap therebetween, and therefore, has made it possible to produce the high-performance dielectric element in which the defects to cause circuit current leakage are removed or reduced.

Further, the invention 12 has enabled the production of the high-quality multilayer dielectric film of a niobium acid nanosheet, and therefore has made it possible to plan and produce the dielectric element having the intended thickness and the intended electrostatic capacitance.

### BRIEF DESCRIPTION OF THE DRAWINGS

FIG. 1 is a graphical structure view of a thin-film element comprising the niobic acid nanosheet thin film of the invention shown in Examples 1 to 3.

FIG. 2 is a result of evaluation of the surface condition of the monolayer film of a niobic acid nanosheet obtained in Example 2, using an atomic force microscope.

FIG. 3 is a result of evaluation of the cross-section structure of a five-layered laminate niobic acid nanosheet thin film shown in Example 2, through observation of the thin film with a high-resolution transmission electronic microscope.

FIG. 4 is a view showing the comparison of the film thickness dependency of the specific permittivity between niobic acid nanosheet thin films shown in Examples 2 and 3 and typical high-permittivity oxide materials.

### DESCRIPTION OF REFERENCE NUMERALS

1. Lower Electrode
2. Niobic Acid Nanosheet
3. Upper Electrode

### BEST MODE FOR CARRYING OUT THE INVENTION

The invention is characterized by the above, and its embodiments are described below.

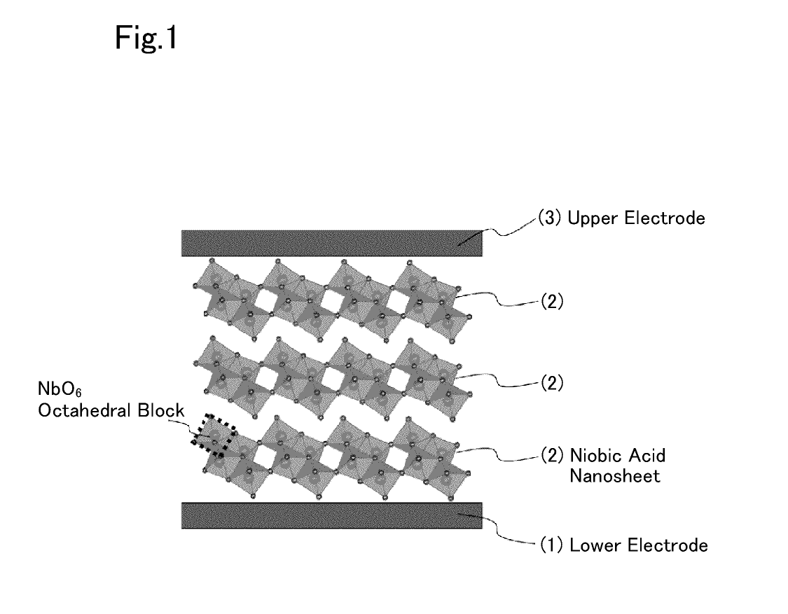

FIG. 1 is a view graphically illustrating the cross-section structure of a thin film element comprising the niobic acid nanosheet multilayer film of one embodiment of the invention. In FIG. 1, (1) means a lower electrode substrate comprising an atomic planar epitaxial SrRuO₃ (this may be hereinafter simply referred to as “substrate (1)”); (2) means a niobic acid nanosheet formed on the substrate (1); and (3) means an upper electrode substrate.

In the embodiment of FIG. 1, a multilayer film of the niobic acid nanosheet (2) is formed on the lower electrode substrate (1) composed of SrRuO₃.

In the invention, the lower electrode substrate (1) is not limited to an atomic planar epitaxial substrate. For example, it may also be a metal electrode of gold, platinum, copper, aluminium or the like, or a conductive perovskite substrate of SrRuO₃, Nb-doped SrTiO₃ or the like, or a transparent oxide electrode of ITO, Ga-doped ZnO, Nb-doped TiO2 or the like, or a substrate of Si, glass, plastic or any others, on which a shin film of niobic acid nanosheets may be formed. Similarly, various types of substances may apply also to the upper electrode (3).

The niobic acid nanosheet (2) (for example, TiNbO₅) to constitute the constitutive layers of the high-permittivity dielectric film is a nano-substance having two-dimensional anisotropy, which can be prepared by soft chemical treatment of a phyllo-structured titanium niobium oxide to cleave it into every minimum layer unit of the crystal structure. The niobium acid nanosheet (2) is illustrated as a nanosheet having a compositional formula TiNbO₅.

The dielectric film of the invention is mainly composed of such a niobic acid nanosheet or a laminate thereof, in which, for example, the niobic acid nanosheet may have a thickness of at most 5 nm (corresponding to a few atoms) capable of expressing high-level atomic confinement, and a lateral size (width and length) of from 100 nm to 100 μm each.

The niobic acid nanosheet of the type may be prepared by cleaving a phyllo-structured niobium oxide, and the phyllo-structured niobium oxide may be any of various types of oxides. For example, preferred are those including NbO₆ octahedrons and TiO₆ octahedrons, or those in which a part of NbO₆ octahedrons are substituted with TaO₆ octahedrons or any others having high-permittivity dielectric functions. For example, the following are exemplified.

### Compositional Formulae:

HₓTiNbO_{5-d}, LiₓTiNbO_{5-d}, NaₓTiNbO_{5-d}, KₓTiNbO_{5-d}, RbₓTiNbO_{5-d}, CsₓTiNbO_{5-d}, HₓTi₂NbO_{7-d}, LiₓTi₂NbO_{7-d}, NaₓTi₂NbO_{7-d}, KₓTi₂NbO_{7-d}, RbₓTi₂NbO_{7-d}, CsₓTi₂NbO_{7-d}, HₓTi₅NbO_{14-d}, LiₓTi₅NbO_{14-d}, NaₓTi₅NbO_{14d}, KₓTi₅NbO_{14-d}, RbₓTi₅NbO_{14-d}, CsₓTi₅NbO_{14-d}, HₓNb₃O_{8-d}, LiₓNb₃O_{8-d}, NaₓNb₃O_{8-d}, KₓNb₃O_{8-d}, RbₓNb₃O_{8-d}, CsₓNb₃O_{8-d}, HₓNb₆O_{17-d}, LiₓNb₆O_{17-d}, NaₓNb₆O_{17-d}, KₓN b₆O_{17-d}, RbₓNb₆O_{17-d}, CsₓNb₆O_{17-d}, HₓTiNb_{1-y}Ta_{y}O_{5-d}, LiₓTiNb_{1-y}Ta_{y}O_{5-d}, NaₓTiNb_{1-y}Ta_{y}O_{5-d}, KₓTiNb_{1-y}Ta_{y}O_{5-d}, RbₓTiNb_{1-y}Ta_{y}O_{5-d}, CsₓTiNb_{1-y}Ta_{y}O_{5-d}, HₓTi₂Nb_{1-y}Ta_{y}O_{7-d}, LiₓTi₂Nb_{1-y}Ta_{y}O_{7-d}, NaₓTi₂Nb_{1-y}Ta_{y}O_{7-d}, KₓTi₂Nb_{1-y}Ta_{y}O_{7-d}, RbₓTi₂Nb_{1-y}Ta_{y}O_{7-d}, CsₓTi₂Nb_{1-y}Ta_{y}O_{7-d}, HₓTi₅Nb_{1-y}, Ta_{y}O_{14-d}, LiₓTi₅Nb_{1-y}, Ta_{y}O_{14-d}, NaₓTi₅Nb_{1-y}, Ta_{y}O_{14-d}, KₓTi₅Nb_{1-y}, Ta_{y}O_{14-d}, RbₓTi₅Nb_{1-y}, Ta_{y}O_{14-d}, CSₓ, Ti₅Nb_{1-y}, Ta_{y}O_{14-d}, Hₓ(Nb_{1-y}, Ta_{y})₃O_{8-d}, Liₓ(Nb_{1-y}Ta_{y})₃O_{8-d}, Naₓ(Nb_{1-y}Ta_{y})₃O_{8-d}, Kₓ(Nb_{1-y}Ta_{y})₃O_{8-d}, Rbₓ(Nb_{1-y}Ta_{y})₃O_{8-d}, Csₓ(Nb_{1-y}Ta_{y})₃O_{8-d}, Hₓ(Nb_{1-y}, Ta_{y})₆O_{17-d}, Liₓ(Nb_{1-y}Ta_{y})₆O_{17-d}, Naₓ(Nb_{1-y}Ta_{y})₆O_{17-d}, Kₓ(Nb_{1-y}, Ta_{y})₆O_{17-d}, Rbₓ(Nb_{1-y}, Ta_{y})₆O_{17-d}, CSₓ(Nb_{1-y}, Ta_{y})₆O_{17-d}, HₓTi_{1-z}Nb_{z}O_{5-d}, LiₓTi_{1-z}Nb_{z}O_{5-d}, Naₓ, Ti_{1-z}Nb_{z}O_{5-d}, KₓTi_{1-z}Nb_{z}O_{5-d}, RbₓTi_{1-z}Nb_{z}O_{5-d}, CsₓTi_{1-z}Nb_{z}O_{5-d}, HₓTi_{2-z}Nb_{z}O_{7-d}, LiₓTi_{2-z}Nb_{z}O_{7-d}, NaₓTi_{2-z}Nb_{z}O_{7-d}, KₓTi_{2-z}Nb_{z}O_{7-d}, RbₓTi_{2-z}Nb_{z}O_{7-d}, CsₓTi_{2-z}N b_{z}O_{7-d}, HₓTi_{5-z}N b_{z}O_{14-d}, LiₓTi_{5-z}Nb_{z}O_{14-d}, NaₓTi_{5-z}Nb_{z}O_{14-d}, KₓTi_{5-z}Nb_{z}O_{14-d}, RbₓTi_{5-z}Nb_{z}O_{14-d}, CSₓTi_{5-z}Nb_{z}O_{14-d}.

In these, 0<x≦3; 0<y≦1; −0.5≦z≦0.5 (excluding z=0); d (oxygen defect)=0 to 2.

The treatment for cleavage is referred to as soft chemical treatment, and the soft chemical treatment is a combined treatment of acid treatment and colloidalization treatment. Specifically, a powder or a single crystal of a phyllo-structured niobium oxide is contacted with an aqueous acid solution such as hydrochloric acid solution or the like, and the product is collected through filtration, washed and dried, whereby the alkali metal ions having existed between the layers before the treatment are all substituted with hydrogen ions to give a hydrogen-type substance. Next, the obtained hydrogen-type substance is put into an aqueous solution of an amine or the like and stirred therein, which is thus colloidalized. In this process, the layers having formed the phyllo-structure are cleaved into the individual layers. The thickness of each layer may be controlled within a range of from sub nm to nm.

The cleaved niobic acid nanosheets may be laminated to give a laminate, based on the alternate self-organization lamination technology already proposed by the present inventors (JP-A 2001-270022, 2004-255684 mentioned above).

In an actual process, a series of operations, (1) dipping a substrate in an organic polycation solution → (2) washing it with pure water → (3) dipping it in a niobic acid nanosheet sol solution → (4) washing it with pure water, as one cycle, are repeated for necessary times. The organic polycation is suitably polyethyleneimine (PEI) described in Examples, as well as polydiallyldimethylammonium chloride (PDDA), polyallylamine hydrochloride (PAH) or the like having a similar cationic property. Regarding the alternate lamination, basically no problem may occur so far as positive charges could be introduced into the substrate surface. Accordingly, any positive charge-having inorganic polymer and polynuclear hydroxide ion-containing inorganic compound can be usable in place of the organic polymer.

Further, in the invention, as the method for forming a monolayer niobic acid nanosheet to be the constitutive layer of the high-permittivity, multilayer dielectric film, there may be provided a method for forming a dielectric monolayer, which comprises coating the surface of a substrate with a niobic acid nanosheet with no gap therebetween and in which mutual overlapping of the nanosheets is removed or reduced.

In this method, for example, the means of coating the surface of a substrate with a niobic acid nanosheet is a method for forming a monolayer according to a process comprising dipping a substrate in a cationic organic polymer solution to thereby make the organic polymer adsorbed by the surface of the substrate, followed by dipping it in a colloid solution where flaky particles are suspended to thereby make the flaky particles adsorbed by the substrate in a mode of self-organization through electrostatic interaction, and the means of treatment for removing and reducing the overlapping part of the niobic acid nanosheets is a method for forming a monolayer according to ultrasonic treatment in an aqueous alkali solution.

In addition, there is also provided a method for formation of a laminate of nano-ultrathin film dielectrics, which comprises repeating the above-mentioned method to thereby form a laminate of niobic acid nanosheets.

Regarding the film formation based on alternate lamination, the surface of the substrate may be good to be fully coated by a nanosheet or a polymer through adsorption, and in place of the alternate self-organization lamination technology, a spin coating method or a dip coating method may also be utilized.

Further, the above-mentioned method makes it possible to form a monolayer or a multilayer of a nano-ultrathin film dielectric substance by removing the organic polymer through irradiation with UV rays. The irradiation with UV rays may be in any mode of irradiation with UV rays containing a wavelength of not more than band gaps at which the photocatalytic organic substance decomposition reaction of niobium oxides is active, and more preferred is irradiation for at least 12 hours with a xenon light source of at least 4 mW/cm².

Apart from the above-mentioned alternate self-organization lamination technology, a similar monolayer film of a niobic acid nanosheet can be formed according to a Langmuir-Blodgett process (hereinafter this may be simply referred to as “LB process”). The LB process is known as a film formation method for a clay mineral or organic nano-thin film in which an association membrane is formed on a vapor-water interface using amphiphilic molecules, and this is drawn up and transferred onto a substrate to produce a uniform monolayer film. Niobic acid nanosheets do not require use of amphiphilic cationic molecules, and when a low-concentration nanosheet sol solution is used, the nanosheets can be adsorbed by a vapor/water interface to give a uniform monolayer film. Accordingly, neither using the organic polymer as in the alternate self-organization lamination technology nor requiring any additional treatment such as ultrasonic densification treatment, a high-quality dielectric film can be produced in which the surface of the substrate is coated with a niobic acid nanosheet closely with no gap.

The invention also provides a method for forming a laminate of nano-ultra-thin film dielectric substances, which comprises repeating the above-mentioned LB process to form a laminate of niobic acid nanosheets.

The invention has realized a production method for a dielectric ultra-thin film or its element, which includes the above-mentioned process as a part of the method.

For example, in the embodiment of Examples mentioned below, a phyllo-structured niobium oxide is used as the starting material to form a niobic acid nanosheet, and as shown in FIG. 1, a multilayer film is formed on an atomic planar epitaxial SrRuO₃ substrate via a cationic polymer therebetween according to alternate self-organization lamination technology or the LB process.

Needless-to-say, the invention is not limited by the following Examples.

### Example 1

In this Example, starting from a phyllo-structured niobium oxide (for example, KTiNbO₅), niobic acid nanosheets (2) are formed, and as shown in FIG. 1, the niobic acid nanosheet (2) and a cationic polymer (4) polyethyleneimine (PEI) are alternately laminated on an atomic planar epitaxial SrRuO₃ substrate (1) to form a multilayer film, in the manner mentioned below.

Phyllo-structured niobium oxide (KTiNbO₅) was prepared by mixing potassium carbonate (K₂CO₃), titanium oxide (TiO₂) and niobium oxide (Nb₂O₅) in a ratio K/Ti/Nb of 1.05/2/1, then calcining it at 900° C. for 1 hour and thereafter firing it at 1100° C. for 20 hours.

One g of the powder was acid-treated in 100 mL of aqueous 1 N hydrochloric acid solution at room temperature to give a hydrogen-exchanged form (HTiNbO₅), then 100 mL of an aqueous solution of tetrabutylammonium hydroxide (hereinafter this is referred to as TBAOH) was added to 0.4 g of the hydrogen-exchanged form and reacted with stirring at room temperature for 10 days, thereby producing a milky white sol solution of, as dispersed therein, rectangular nanosheets (2) represented by a compositional formula TiNbO₅ and having a thickness of about 1 nm and a lateral size of from 100 nm to 5 μm.

A conductive substrate (1) to be the lower electrode of atomic planar epitaxial SrRuO₃ was washed on the surface thereof through UV irradiation in an ozone atmosphere, then dipped in a solution of hydrochloric acid/methanol=1/1 for ⅓ hours, and in concentrated sulfuric acid for ⅓ hours for hydrophilication treatment.

The substrate (1) was repeatedly processed for a series of operations as one cycle mentioned below, for a total of the necessary cycles, thereby forming a niobic acid nanosheet thin film having a thickness necessary for the desired dielectric film.

[1] Dipping in the above-mentioned PEI solution for ⅓ hours.

[2] Washing fully with Milli-Q pure water.

[3] Dipping in the above-mentioned nanosheet sol solution with stirring.

[4] After ⅓ hours, washing fully with Milli-Q pure water.

[5] With dipping the formed thin film in aqueous TBAOH solution at pH 11, ultrasonically treating in an ultrasonic washer tank (Branson's 42 kHz, 90 W) for ⅓ hours.

Thus formed, the niobic acid nanosheet thin film was UV-irradiated with a xenon light source (4 mW/cm², 72 hours), thereby producing a thin film of niobic acid nanosheets (2) from which the organic polymer had been removed through photocatalytic reaction of the niobic acid nanosheets.

Table 1 shows the data of the leak current density and the specific permittivity of the thin film elements (dielectric elements) comprising the multilayer niobic acid nanosheet thin film, in which the number of laminated layers was 10, and a gold electrode serving as the upper electrode. The leak current density is a current density measured with a semiconductor parameter analyzer (Keithley's 4200-SCS) with voltage application of +1V to the sample. On the other hand, for the specific permittivity, the electrostatic capacity was measured with a high-precision impedance analyzer (Agilent Technology's 4294A) at a frequency of 10 kHz, and the specific permittivity was computed from the data.

TABLE 1

| | Number of | | | |
|---|---|---|---|---|
| Compo- | Laminated | Film | Leak Current | Specific |
| sition | Layers | Thickness | density | Permittivity |
| TiNbO₅ | 10 | 10 nm | 3.0 × 10⁻⁶ A/cm² | 145 |

Table 1 shows that the leak current property of the dielectric film comprising the multilayer niobic acid nanosheet thin film was on a level of 10⁻⁶ A/cm² though the film thickness was 10 nm and was ultra-thin, and the dielectric film exhibited good insulating properties. The dielectric film was compared with existing titanium oxide dielectric substance (Ba,Sr)TiO₃ and rutile-type TiO₂ having the same thickness of 10 nm, in point of the leak current density therethrough, and the leak current through the former was prevented more effectively by about 100 times than that through the latter, and the dielectric film of the invention exhibited extremely excellent insulating properties. In addition, the specific permittivity of the multilayer niobic acid nanosheet thin film in this Example was a high value of 145, which is at least 2 times higher than that of existing titanium oxide dielectric substance (Ba,Sr)TiO₃ and rutile-type TiO₂.

### Example 2

In this Example, starting from a phyllo-structured niobium oxide (for example, KTiNbO₅), niobic acid nanosheets (TiNbO₅) were formed, and as shown in FIG. 1, a multilayer film of the niobic acid nanosheets (2) was formed on the lower electrode substrate, atomic planar epitaxial SrRuO₃ substrate (1) according to the LB process (Langmuir-Blodgett process) in the manner mentioned below.

According to the same method as in Example 1, a phyllo-structured niobium oxide (KTiNbO₅) was cleaved into single layers, thereby producing a milky white sol solution with, as dispersed therein, rectangular nanosheets having a compositional formula TiNbO₅ and having a thickness of about 1 nm and a lateral size of from 100 nm to 5 μm.

The surface of the conductive substrate (1) composed of atomic planar epitaxial SrRuO₃, which is to be the lower electrode, was washed through irradiation with UV rays in an ozone atmosphere, and this was dipped in a solution of hydrochloric acid/methanol=1/1 for ⅓ hours, and then dipped in concentrated sulfuric acid for ⅓ hours for hydrophilication treatment.

In a measuring flask, 1 mL of the niobic acid nanosheet sol solution was dispersed in 249 mL of ultra-pure water thereby preparing a solution having a controlled concentration. The dispersion was left as such for about a half day to one day or so, and then the dispersion was spread on an LB trough well washed with acetone, and kept as such for ½ hours for which the liquid surface was stabilized and the temperature of the lower layer liquid reached constant. Next, the above-prepared substrate (1) was set in an LB film formation apparatus, and processed according to a series of the following operations as one cycle, repeatedly for the necessary number of cycles, thereby producing a niobic acid nanosheet thin film having a desired film thickness.

[1] The barrier is compressed at a compression speed of 0.5 mm/sec, whereby the perovskite nanosheets dispersed on the vapor/water interface are collected, and after the system has reached a predetermined pressure, this is statically kept as such for ½ hours. In that manner, a monolayer film is formed in which the niobic acid nanosheets are aligned in parallel and are integrated in the vapor/water interface.

[2] The substrate (1) is vertically drawn up at a drawing speed of 1 mm/sec. Accordingly, the monolayer film is attached to the substrate, thereby producing a thin film in which the niobic acid nanosheets are closely packed.

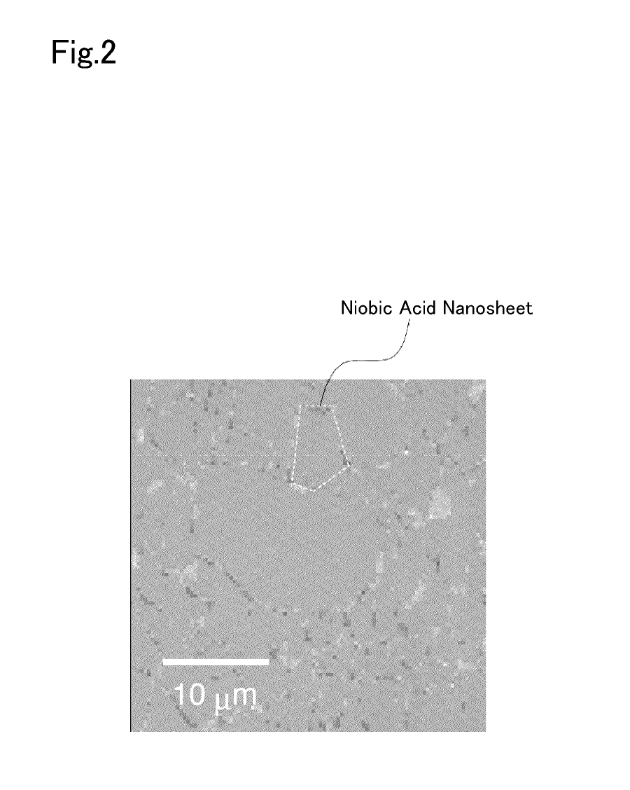

FIG. 2 is a result of evaluation in observation with an atomic force microscope of the surface condition of the thus-formed monolayer film of niobic acid nanosheets. This confirms the formation of the monolayer film of niobic acid nanosheets having a dense and atomic-level surface planarity, in which the substrate surface is coated with the nanosheets with no gap therebetween. As seen on the AFM picture image, the thickness of the monolayer film of niobic acid nanosheets is about 1 nm, and this corresponds nearly to the thickness of one monolayer nanosheet.

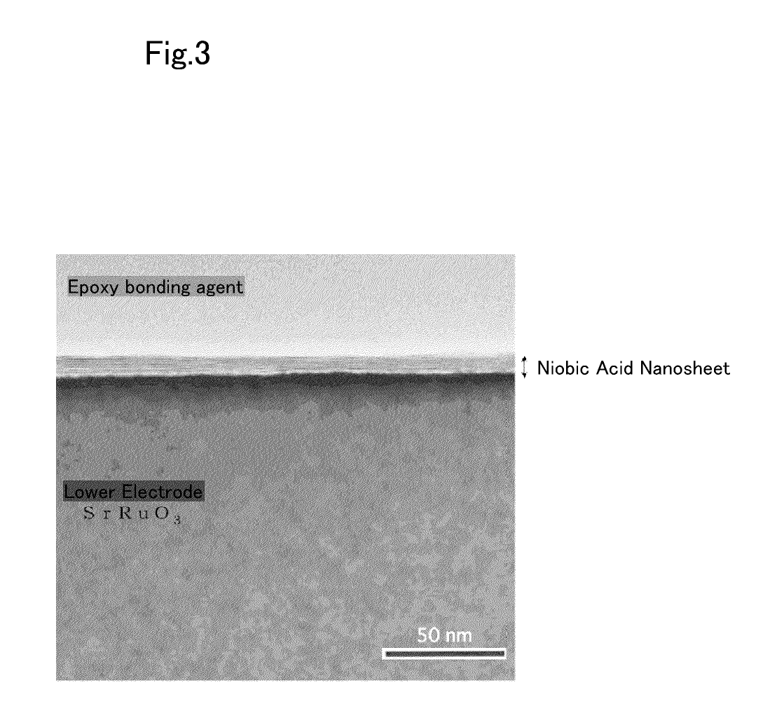

FIG. 3 is a result of evaluation in observation with a high-resolution transmitting electronic microscope of the cross-section structure of the thus-produced, five-layered niobic acid nanosheet thin film. Two samples of the five-layered niobic acid nanosheet film were prepared for the measurement, and these were bonded with an epoxy resin, and then cut according to an ion-milling method. According to the method, a thin flaky sample can be obtained, favorable for observation of the cross section thereof with a high-resolution transmitting electronic microscope. Obviously in FIG. 3, a multilayer structure of niobic acid nanosheets accumulated in five layers and in parallel to each other on an atomic level on the electrode is confirmed. It can be said that a high-quality multilayer film was realized, in which monolayer films were laminated layer by layer with securing the compactness and the smoothness of the monolayer films. The matter that should be further noted in FIG. 3 is that there was formed neither a low-dielectric layer nor an interlayer accompanied by the substrate interface deterioration and the composition deviation in thermal annealing in the production process, which was problematic in existing high-permittivity oxide materials, between the lower electrode (1) and the niobic acid nanosheet thin film. This supports the remarkable effect of the invention in that the production process for the multilayer niobic acid nanosheet thin film of this Example is based on a room-temperature solution process free from the influence of substrate interface deterioration and composition deviation thereon.

Table 2 shows the data of the leak current density and the specific permittivity of the dielectric elements comprising, as the dielectric thin film, a 5-layered or 10-layered laminate of monolayer films, and comprising a gold electrode as the upper electrode. The leak current density is a current density measured with a semiconductor parameter analyzer (Keithley's 4200-SCS) with voltage application of +1V to the sample. On the other hand, for the specific permittivity, the electrostatic capacity was measured with a high-precision impedance analyzer (Agilent Technology's 4294A) at a frequency of 10 kHz, and the specific permittivity was computed from the data.

TABLE 2

| | Number of | | | |
|---|---|---|---|---|
| Compo- | Laminated | Film | Leak Current | Specific Dielectric |
| sition | Layers | Thickness | Density | Constant |
| TiNbO₅ | 5 | 5 nm | 1.2 × 10⁻⁶ A/cm² | 157 |
| TiNbO₅ | 10 | 10 nm | 5.3 × 10⁻⁷ A/cm² | 155 |

Table 2 shows that the leak current property of the dielectric elements comprising the monolayer film was on a level of at most 10⁻⁶ A/cm² though the film thickness was from 5 to 10 nm and was ultra-thin, and the dielectric elements all exhibited good insulating properties. The dielectric elements of the invention were compared with existing dielectric elements comprising a titanium oxide dielectric substance (Ba,Sr)TiO₃, rutile-type TiO₂ or the like, in which the thickness of the dielectric thin film was 10 nm, in point of the leak current density therethrough, and the leak current through the former was prevented more effectively by about 1000 times than that through the latter, and the dielectric elements of the invention exhibited extremely excellent insulating properties. In addition, the specific permittivity of the dielectric elements comprising a monolayer film of the invention was at least 150 irrespective of the number of the laminated layers, and was high.

### Example 3

In this Example, starting from a phyllo-structured niobium oxide (for example, CsTi₂NbO₇, K₃Ti₅NbO₁₄, KNb₃O₈), niobic acid nanosheets (Ti₂NbO₇, Ti₅NbO₁₄, Nb₃O₈) were formed, and as shown in FIG. 1, a multilayer film of the niobic acid nanosheets (2) was formed on the lower electrode substrate, atomic planar epitaxial SrRuO₃ substrate (1) according to the LB process (Langmuir-Blodgett process) in the manner mentioned below.

The niobic acid nanosheets (Ti₂NbO₇, Ti₅NbO₁₄, Nb₃O₈) were formed according to the methods mentioned below.

### <Ti₂NbO₇ Nanosheets>

Phyllo-structured oxide CsTi₂NbO₇ was prepared by mixing cesium nitrate (CsNO₃), titanium oxide (TiO₂) and niobium oxide (Nb₂O₅) in a ratio Cs/Ti/Nb of 2.1/4/1, then calcining it at 950° C. for ½ hours and thereafter firing it at 1100° C. for 20 hours. One g of the powder was acid-treated in 100 mL of aqueous 1 N hydrochloric acid solution at room temperature to give a hydrogen-exchanged form (HTi₂NbO₇), then 100 mL of an aqueous solution of tetrabutylammonium hydroxide (hereinafter this is referred to as TBAOH) was added to 0.4 g of the hydrogen-exchanged form and reacted with stirring at room temperature for 10 days, thereby producing a milky white sol solution of, as dispersed therein, rectangular nanosheets (2) represented by a compositional formula TiNbO₅ and having a thickness of about 1 nm and a lateral size of from 100 nm to 5 μm.

### <Ti₅NbO₁₄ Nanosheets>

Phyllo-structured oxide K₃Ti₅NbO₁₄ was prepared by mixing potassium carbonate (K₂CO₃), titanium oxide (TiO₂) and niobium oxide (Nb₂O₅) in a ratio K/Ti/Nb of 3/10/1, then calcining it at 900° C. for 1 hour and thereafter firing it at 1000° C. for 12 hours. One g of the powder was acid-treated in 100 mL of aqueous 1 N hydrochloric acid solution at room temperature to give a hydrogen-exchanged form (H₃Ti₅NbO₁₄), then 100 mL of an aqueous solution of tetrabutylammonium hydroxide (hereinafter this is referred to as TBAOH) was added to 0.4 g of the hydrogen-exchanged form and reacted with stirring at room temperature for 10 days, thereby producing a milky white sol solution of, as dispersed therein, rectangular nanosheets (2) represented by a compositional formula TiNbO₅ and having a thickness of about 1 nm and a lateral size of from 100 nm to 5 μm.

### <Nb₃O₈ Nanosheets>

Phyllo-structured oxide KNb₃O₈ was prepared by mixing potassium nitrate (KNO₃) and niobium oxide (Nb₂O₅) in a ratio K/Nb of 2/3, then keeping it at 600° C. for 2 hours, heating it from 600° C. up to 900° C. for 2 hours for calcination, and thereafter firing it at 900° C. for 20 hours. One g of the powder was acid-treated in 100 mL of aqueous 2 N nitric acid solution at room temperature to give a hydrogen-exchanged form (HNb₃O₈), then 100 mL of an aqueous solution of tetrabutylammonium hydroxide (hereinafter this is referred to as TBAOH) was added to 0.4 g of the hydrogen-exchanged form and reacted with stirring at room temperature for 10 days, thereby producing a milky white sol solution of, as dispersed therein, rectangular nanosheets (2) represented by a compositional formula TiNbO₅ and having a thickness of about 1 nm and a lateral size of from 100 nm to 5 μm.

A conductive substrate (1) to be the lower electrode of atomic planar epitaxial SrRuO₃ was washed on the surface thereof through UV irradiation in an ozone atmosphere, then dipped in a solution of hydrochloric acid/methanol=1/1 for ⅓ hours, and in concentrated sulfuric acid for ⅓ hours for hydrophilication treatment.

In a 1-L measuring flask, 8 mL of the niobic acid nanosheet sol solution was dispersed in ultra-pure water. The dispersion was left as such for about a half day to one day or so, and then the dispersion was spread on an LB trough well washed with acetone, and kept as such for ½ hours for which the liquid surface was stabilized and the temperature of the lower layer liquid reached constant. Next, the above-prepared substrate (1) was processed according to a series of the following operations as one cycle, repeatedly for the necessary number of cycles, thereby producing a niobic acid nanosheet thin film having a desired film thickness.

[1] The barrier is compressed at a compression speed of 0.5 mm/sec, whereby the nanosheets dispersed on the vapor/water interface are collected, and after the system has reached a predetermined pressure, this is statically kept as such for ½ hours. In that manner, a monolayer film is formed in which the niobic acid nanosheets are aligned in parallel and are integrated in the vapor/water interface.

[2] The substrate is vertically drawn up at a drawing speed of 1 mm/sec. Accordingly, the monolayer film is attached to the substrate, thereby producing a thin film in which the niobic acid nanosheets are closely packed.

Table 3 collectively shows the data of the maximum specific permittivity measured as the leak current density in the dielectric elements comprising the monolayer niobic acid nanosheet film (Ti₂NbO₇, Ti₅NbO₁₄, Nb₃O₈), in which the number of laminated layers was 10, and a gold electrode serving as the upper electrode. The leak current density is a current density measured with a semiconductor parameter analyzer (Keithley's 4200-SCS) with voltage application of +1V to the sample. On the other hand, for the specific permittivity, the electrostatic capacity was measured with a high-precision impedance analyzer (Agilent Technology's 4294A) at a frequency of 10 kHz, and the specific permittivity was computed from the data.

TABLE 3

| | Number of | | | |
|---|---|---|---|---|
| Compo- | Laminated | Film | Leak Current | Specific |
| sition | Layers | Thickness | density | Permittivity |
| Ti₂NbO₇ | 10 | 10 nm | 6.7 × 10⁻⁷ A/cm² | 307 |
| Ti₅NbO₁₄ | 10 | 10 nm | 8.4 × 10⁻⁷ A/cm² | 297 |
| Nb₃O₈ | 10 | 10 nm | 4.5 × 10⁻⁵ A/cm² | 71 |

As in Table 3, the leak current property of all the multilayer niobic acid nanosheet thin films was on a level of at most 10⁻⁵ A/cm² though the film thickness was 10 nm and was ultra-thin, and the niobic acid nanosheet thin films all exhibited good insulating properties. In addition, the specific permittivity of the multilayer niobic acid nanosheet thin films was from 71 to 307 and was high.

As shown in Examples 1 to 3 in the above, the niobic acid nanosheet thin films of the invention have an excellent specific permittivity in a thin film region on a level of 10 nm, much superior to existing high-permittivity oxide materials.

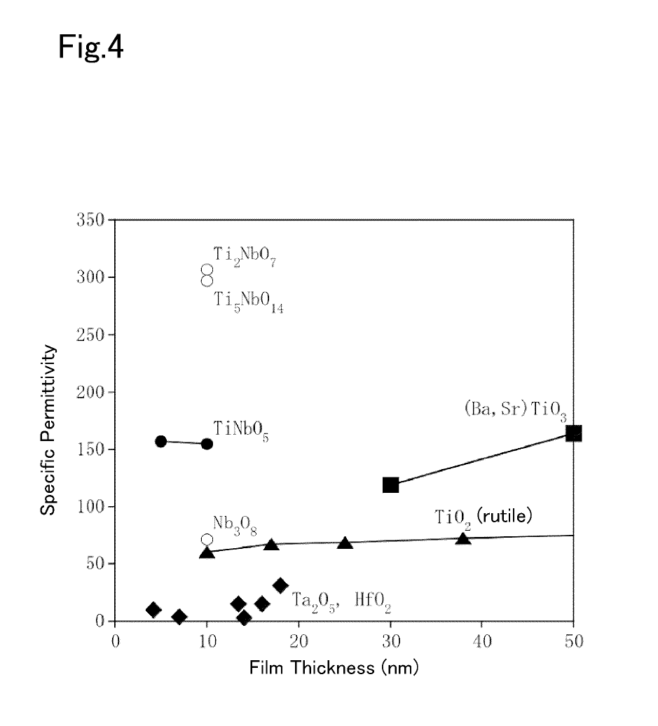

FIG. 4 shows plotted data of the specific permittivity in an ultra-thin film region of the niobic acid nanosheet thin film dielectric elements shown in Examples 2 and 3. In addition, this shows, for comparison, the film thickness dependence of the specific permittivity of typical high-permittivity oxide materials. When an existing high-permittivity material oxide, for example, (Ba,Sr)TiO₃ is thinned to a nano-level for the purpose of attaining increased capacity, then the specific permittivity thereof lowers; but contrary to this, the niobic acid nanosheet thin films of the invention are free from any remarkable size effect, and kept a high specific permittivity of at least 100 even though they had a thickness of from around 5 to 10 nm and were thin. The matter to be specifically noted is that the niobic acid nanosheet thin films of the invention have a greatly larger specific permittivity in a thin film region on a level of 10 nm, far over any other existing high-permittivity oxide materials. Accordingly, the invention has an epoch-making effect of bringing about size-free high permittivity properties capable of realizing both a high permittivity and good insulating properties in a nano-scale region.

When the multilayer niobic acid nanosheet thin film produced in the manner as above is applied to DRAM memories and others, then it is possible to obtain devices having a higher capacity by at least dozens of times than existing high-permittivity oxide materials having the same film thickness. Further, the invention has other excellent effects in that leak current can be prevented and consuming current can be reduced and that, in increased memory and transistor integrations, various types (trench type or stack type) of devices can be designed in any desired manner.

The embodiments in the above are for describing the invention with reference to an example of forming a multilayer niobic acid nanosheet thin film on an atomic planar epitaxial SrRuO₃ substrate and applying it to a DRAM memory; however, the dielectric element of the invention can be used as a thin-film capacitor by itself, and can also be used for gate insulators for transistors, multilayer capacitors for mobile telephones, high-frequency devices and others, exhibiting the same excellent effects.

The invention has made it possible to utilize peculiar nano-properties and good ability of texture and structure regulation that the niobic acid nanosheet of a two-dimensional nanostructure has, and has realized both high permittivity and good insulating properties even in a nano-region. In particular, using the niobic acid nanosheets of the invention, the invention has enabled artificial reconstruction of NbO6 octahedron blocks of high-function dielectric blocks, and has therefore realized high-level dielectric polarization caused by the nano-size high-level atomic confinement therein, and has made it possible to produce and plan the thin film having more excellent dielectric properties than existing titanium oxide dielectric substances. Further, the niobic nanosheets can be worked into devices through soft chemical reaction such as room-temperature self-organization, and can be therefore integrated with various materials not being troubled by problems of substrate interface deterioration and composition deviation in thermal annealing in existing semiconductor production processes.

Further, the invention has realized the inexpensive, low environmental-load process not requiring a large-scale vacuum apparatus and an expensive film formation apparatus that are the mainstream of existing semiconductor processes and dielectric film processes. Accordingly, it is concluded that the high-permittivity nanomaterial of the invention is extremely useful in application thereof to the technical field of electronic materials, IT technology material, nanoelectronics and others, for example, to DRAM memory for personal computers, gate insulator for transistors, multilayer capacitor for mobile telephones, high-frequency devices and others in which a high-permittivity material constitutes the backbone parts thereof.

### INDUSTRIAL APPLICABILITY

High-permittivity materials are used in all electronic instruments such as DRAM memory for personal computers, gate insulator for transistors, multilayer capacitor for mobile telephones, high-frequency devices and others, and the members of industry, government and academia around the world are now under tough competition in studies and developments aimed at the practical realization of high-permittivity materials within 10 years in place of the current SiO₂ and SiN_{X}. From these points and inconsideration of the facts that the nanomaterial we have developed this time (1) can function as a thinnest film among existing materials, and realizes simultaneously both high permittivity and good insulating properties, (2) can be worked into devices according to a room-temperature, inexpensive solution process, (3) can solve all the problems accompanied with existing thermal annealing, as having realized the room-temperature process, and (4) has realized an inexpensive and low-environmental load process not requiring a large-size vacuum apparatus and an expensive film formation apparatus that are the mainstream of existing semiconductor dielectric film processes, etc., the economical advantages of the invention are obvious.

1. A dielectric film of a monolayer or a laminate of a nanosheet composed of niobic acid octahedral blocks.

2. The dielectric film as claimed in claim 1, wherein the niobic acid nanosheet is represented by any of compositional formulae TiNbO_{5-d}, Ti₂NbO_{7-d}, Ti₅NbO_{14-d}, Nb₃O_{8-d}, Nb₆O_{17-d}, TiNb_{1-y}Ta_{y}O_{5-d}, Ti₂Nb_{1-y}Ta_{y}O_{7-d}, Ti₅Nb_{1-y}Ta_{y}O_{14-d}, (Nb_{1-y}Ta_{y})₃O_{8-d}, (Nb_{1-y}Ta_{y})₆O_{17-d}, Ti_{1-z}Nb_{z}O₅, Ti_{2-z}Nb_{z}O₇, Ti_{5-z}Nb_{z}O₁₄(0<y≦1; −0.5≦z≦0.5 (excluding z=0); d (oxygen defect)=0 to 2).

3. The dielectric film as claimed in claim 1, wherein the nanosheet has a sheet-like form having a thickness of at most 5 nm (corresponding to a few atoms) and a lateral size of from 100 nm to 100 μm.

4. The dielectric film as claimed in claim 1, wherein the nanosheet is obtained by cleaving any of the phyllo-structured niobium oxides or their hydrates represented by the following compositional formulae:
Compositional Formulae: AₓTiNbO_{5-d}, AₓTi₂NbO_{7-d}, AₓTi₅NbO_{14-d}, AₓNb₃O_{8-d}, AₓNb₆O_{17-d}, AₓTiNb_{1-y}Ta_{y}O_{5-d}, AₓTi₂Nb_{1-y}Ta_{y}O_{7-d}, AₓTi₅Nb_{1-y}Ta_{y}O_{14-d}, Aₓ(Nb_{1-y}Ta_{y})₃O_{8-d}, Aₓ(Nb_{1-y}Ta_{y})₆O_{17-d}, AₓTi_{1-z}Nb_{z}O₅, AₓTi_{2-z}Nb_{z}O₇, AₓTi_{5-z}Nb_{z}O₁₄
(wherein A is at least one selected from H, Li, Na, K, Rb, Cs; 0<x≦3; 0<y≦1; −0.5≦z≦0.5 (excluding z=0); d (oxygen defect)=0 to 2).

5. A dielectric element comprising electrodes arranged on and below a dielectric film, wherein the dielectric film is the dielectric film of claim 1.

6. The dielectric element as claimed in claim 5, wherein the thickness of the dielectric film is at most 20 nm and the specific permittivity thereof is at least 50.

7. A method for producing a dielectric element comprising electrodes arranged on and below a dielectric film, which comprises attaching a monolayer or a multilayer of the niobic acid nanosheet of claim 1 to at least one electrode substrate to constitute the dielectric element, thereby forming a dielectric film, and arranging other electrode on the surface of the dielectric film.

8. The method for producing a dielectric element as claimed in claim 7, wherein an electrode substrate having adsorbed a cationic organic polymer on its surface is dipped in a colloid solution where the niobium acid nanosheets are suspended, and the niobic acid nanosheets are thereby adsorbed by the polymer through electrostatic interaction.

9. The method for producing a dielectric element as claimed in claim 8, wherein the dielectric film is, after formed, irradiated with UV rays to thereby remove the organic polymer from the substrate surface.

10. The method for producing a dielectric element as claimed in claim 7, wherein a monolayer film is formed in which niobic acid nanosheets are bonded in parallel to each other according to a Langmuir-Blodgett process, and the monolayer film is attached to the electrode substrate

11. The method for producing a dielectric element as claimed in claim 7, wherein ultrasonic waves are given to the niobic acid nanosheets being attached to the substrate to thereby remove the overlapped part of the nanosheets.

12. The method for producing a dielectric element as claimed in claim 7, wherein the step of attaching the titanium niobic acid nanosheets to the electrode substrate is repeated to form a multilayered dielectric film of the niobic acid nanosheets.
